(19) United States
(12) Patent Application Publication
(10) Pub. No.: US 2025/0183097 A1
(43) Pub. Date: Jun. 5, 2025

(54) LOW RESISTIVITY CONTACTS AND INTERCONNECTS

(71) Applicant: Lam Research Corporation, Fremont, CA (US)

(72) Inventors: Chiukin Steven LAI, Sunnyvale, CA (US); Jeong-Seok NA, San Jose, CA (US)

(21) Appl. No.: 18/253,038

(22) PCT Filed: Nov. 4, 2021
(86) PCT No.: PCT/US2021/058099

§ 371 Date: May 16, 2023

Related U.S. Application Data
(60) Provisional application No. 63/198,880, filed on Nov. 19, 2020.

(51) Int. Cl. H01L 21/768; C23C 16/02; C23C 16/04; C23C 16/08; C23C 16/18; C23C 16/455; H01L 21/3205

(52) U.S. Cl. CPC H01L 21/76883; C23C 16/02; C23C 16/045; C23C 16/08; C23C 16/18; C23C 16/45525; H01L 21/32051

(57) ABSTRACT

Metallization schemes involve atomic layer deposition (ALD) of molybdenum (Mo) and in some embodiments, ALD of Mo in a feature without a barrier layer. In some embodiments, deposition of the ALD Mo film may be followed by chemical vapor deposition (CVD) or physical vapor deposition (PVD) of a Mo film. In some embodiments, the CVD or PVD Mo film is part of the metallization stack. In other embodiments, the CVD or PVD Mo film is deposited as a sacrificial overburden layer. In some embodiments, deposition of the ALD Mo film may be followed by CVD or PVD of another metal such as tungsten (W). In some embodiments, the CVD or PVD W film is part of the metallization stack. In other embodiments, the CVD or PVD W film is deposited as a sacrificial overburden layer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Deposition of metals is an integral part of many semiconductor fabrication processes. These materials may be used for horizontal interconnects, vias between adjacent metal layers, and contacts between metal layers and devices. However, as devices shrink and more complex patterning schemes are utilized in the industry, deposition of low resistivity metal films becomes a challenge.

### SUMMARY

One aspect of the disclosure relates to a method including: depositing a bulk layer of molybdenum (Mo) by atomic layer deposition (ALD) in a structure including a plurality of features to at least partially fill the plurality of features with Mo; and depositing a bulk layer of tungsten (W) on the bulk layer of Mo by chemical vapor deposition (CVD) or physical vapor deposition (PVD).

In some embodiments, the plurality of features includes a first set of one or more features having a first critical dimension and a second set of one or more features having a second critical dimension, the first critical dimension being smaller than the second critical dimension and wherein fill of the features of the first set is completed by depositing the bulk layer of Mo and fill of the features of the second set is completed by depositing the bulk layer of W. In some embodiments, the fill of at least some of the plurality of features is completed by the bulk layer of W. In some embodiments, the bulk layer of W is deposited only over the top of the plurality of features and is not within the plurality of features. In some embodiments, the method further includes removing all of the bulk layer of W. In some embodiments, the plurality of features includes oxide surfaces prior to any Mo deposition in the features. In some such embodiments, Mo is formed in the plurality of features without a barrier layer disposed between the formed Mo and the oxide surfaces.

In some embodiments, the method further includes depositing a nucleation layer prior to depositing the bulk layer of Mo. In some such embodiments, depositing the nucleation layer includes forming a layer of molybdenum nitride or molybdenum oxynitride. In some such embodiments, the method further includes converting the layer of molybdenum nitride or molybdenum oxynitride to molybdenum.

In some embodiments, the bulk layer of Mo and the bulk layer of W are deposited in the same chamber. In some embodiments, the bulk layer of Mo and the bulk layer of W are deposited in different stations of the same chamber. In some embodiments, the bulk layer of Mo and the bulk layer of W are deposited in different chambers. In some such embodiments, the different chambers are coupled to a common vacuum environment and in other such embodiments the different chambers are not coupled to a common vacuum environment.

In some embodiments, the method further includes treating the surface of the deposited bulk layer of Mo with a metal halide prior to depositing the bulk layer of W.

In some embodiments, depositing a bulk layer of Mo by atomic layer deposition (ALD) includes exposing the structure to alternating pulses of a Mo precursor and a co-reactant. In some such embodiments, the Mo precursor is a molybdenum halide or molybdenum oxyhalide. In some such embodiments, the Mo precursor is one of molybdenum hexafluoride (MoF₆), molybdenum hexachloride (MoCl₅), molybdenum dichloride dioxide (MoO₂Cl₂) molybdenum tetrachloride oxide (MoOCl₄), molybdenum hexacarbonyl (Mo(CO)₆), (MoOF₄), molybdenum dibromide dioxide (MoO₂Br₂), MoO₂I, and Mo₄O₁₁I. In some embodiments, the co-reactant is hydrogen (H₂). In some embodiments, the Mo precursor is an organo-metallic precursor.

Another aspect of the disclosure relates to a method including: providing a structure including a first set of features to a chamber; depositing a bulk layer of molybdenum (Mo) by atomic layer deposition (ALD) in a structure including a first set of features to partially fill features with Mo; and transferring the structure including the features partially filled with Mo out of the chamber. In some embodiments, depositing a bulk layer of Mo by atomic layer deposition (ALD) includes exposing the structure to alternating pulses of a Mo precursor and a co-reactant. In some such embodiments, the Mo precursor is a molybdenum halide or molybdenum oxyhalide. In some such embodiments, the Mo precursor is one of molybdenum hexafluoride (MoF₆), molybdenum hexachloride (MoCl₅), molybdenum dichloride dioxide (MoO₂Cl₂) molybdenum tetrachloride oxide (MoOCl₄), molybdenum hexacarbonyl (Mo(CO)₆), (MoOF₄), molybdenum dibromide dioxide (MoO₂Br₂), MoO₂I, and Mo₄O₁₁I. In some embodiments, the co-reactant is hydrogen (H₂). In some embodiments, the Mo precursor is an organo-metallic precursor.

In some embodiments, the method further includes depositing a nucleation layer prior to depositing the bulk layer of Mo. In some such embodiments, depositing the nucleation layer includes forming a layer of molybdenum nitride or molybdenum oxynitride. In some such embodiments, the method further includes converting the layer of molybdenum nitride or molybdenum oxynitride to molybdenum.

Yet another aspect of the disclosure relates to a method including: providing a structure including a first set of features to a chamber, wherein the first set of features are at least partially filled with molybdenum (Mo); and depositing a bulk layer of tungsten (W) on the Mo.

In some embodiments, the structure includes a plurality of features including the first set of one or more features, which have a first critical dimension, and a second set of one or more features having a second critical dimension, the first critical dimension being smaller than the second critical dimension and wherein the features of the first set are completely filled with Mo and fill of the features of the second set is completed by depositing the bulk layer of W.

In some embodiments, the fill of at least some of the first set of features is completed by the bulk layer of W. In some embodiments, the bulk layer of W is deposited only over the top of the first set of features and is not within the first set of features.

In some embodiments, the method further includes removing all of the bulk layer of W. In some embodiments, Mo is disposed in the plurality of features without a barrier layer disposed between the formed Mo and oxide surfaces.

These and other aspects of the disclosure are described further below with reference to the drawings.

### BRIEF DESCRIPTION OF DRAWINGS

FIG. 1A is a schematic example of a cross-section of a structure having different sized features to be filled with conductive material.

FIG. 1B is a schematic example showing the structure of FIG. 1a after atomic layer deposition (ALD) of a molybdenum (Mo) film.

FIG. 1C is a schematic example showing the structure of FIG. 1b after chemical vapor deposition (CVD) of a tungsten (W) film.

FIG. 1D is a schematic example showing the structure of FIG. 1c after chemical-mechanical planarization (CMP).

FIG. 2 is a schematic example of a structure in which an ALD Mo film completely fills smaller features and partially fills larger features with CVD Mo film filling the remaining part of the larger features.

FIG. 3A is a schematic example of the structure of FIG. 1a after ALD of a Mo film to completely fill the structure features.

FIG. 3B is a schematic example of the structure of FIG. 1b after CVD of a W overburden film.

FIG. 3C is a schematic example showing the structure of FIG. 3b after chemical-mechanical planarization (CMP).

FIG. 4 is a flow diagram showing certain operations in an example of an ALD method of forming a Mo film.

FIGS. 5 and 6 are flow diagrams showing certain operations in examples of methods of depositing Mo.

FIG. 7 is a flow diagram showing certain operations in an example of method of treating Mo with a metal halide prior to CVD deposition of W.

FIG. 8 depicts a schematic illustration of an example process station that may be used for ALD and/or CVD.

FIG. 9 shows an example of a processing system including multiple chambers.

### DETAILED DESCRIPTION

Provided herein are low resistance metallization stack structures for logic and memory applications and related methods of fabrication. The methods involve atomic layer deposition (ALD) of molybdenum (Mo) and in some embodiments, ALD of Mo in a feature without a barrier layer. In some embodiments, deposition of the ALD Mo film may be followed by chemical vapor deposition (CVD) or physical vapor deposition (PVD) of a Mo film. In some embodiments, the CVD or PVD Mo film is part of the metallization stack. In other embodiments, the CVD or PVD Mo film is deposited as a sacrificial overburden layer. In some embodiments, deposition of the ALD Mo film may be followed by CVD or PVD of another metal such as tungsten (W). In some embodiments, the CVD or PVD W film is part of the metallization stack. In other embodiments, the CVD or PVD W film is deposited as a sacrificial overburden layer. The metallization may be performed in any appropriate context including middle of the line (MOL) and back end of line (BEOL) metallization.

According to various embodiments, one or more advantages may be realized. In some embodiments, the low resistivity films may be deposited directly in etched dielectric without a diffusion barrier or other intervening film. This can lower resistivity. In some embodiments, the process is efficient and highly scalable, with a relatively fast CVD or PVD process used to fill large features and/or overburden layers.

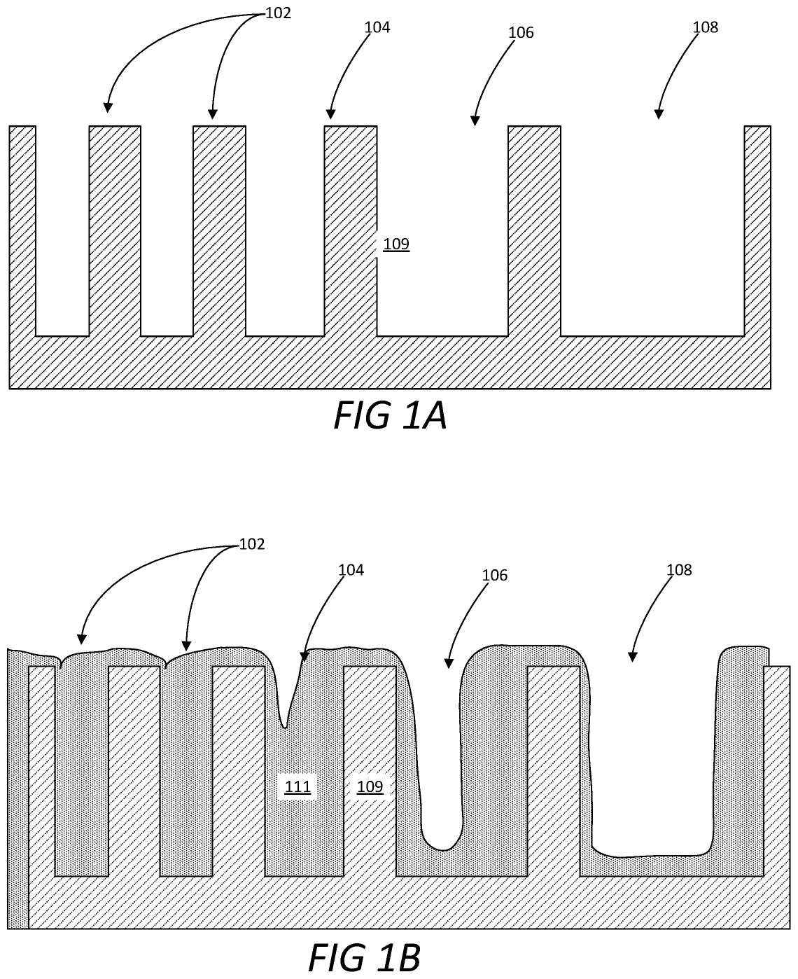

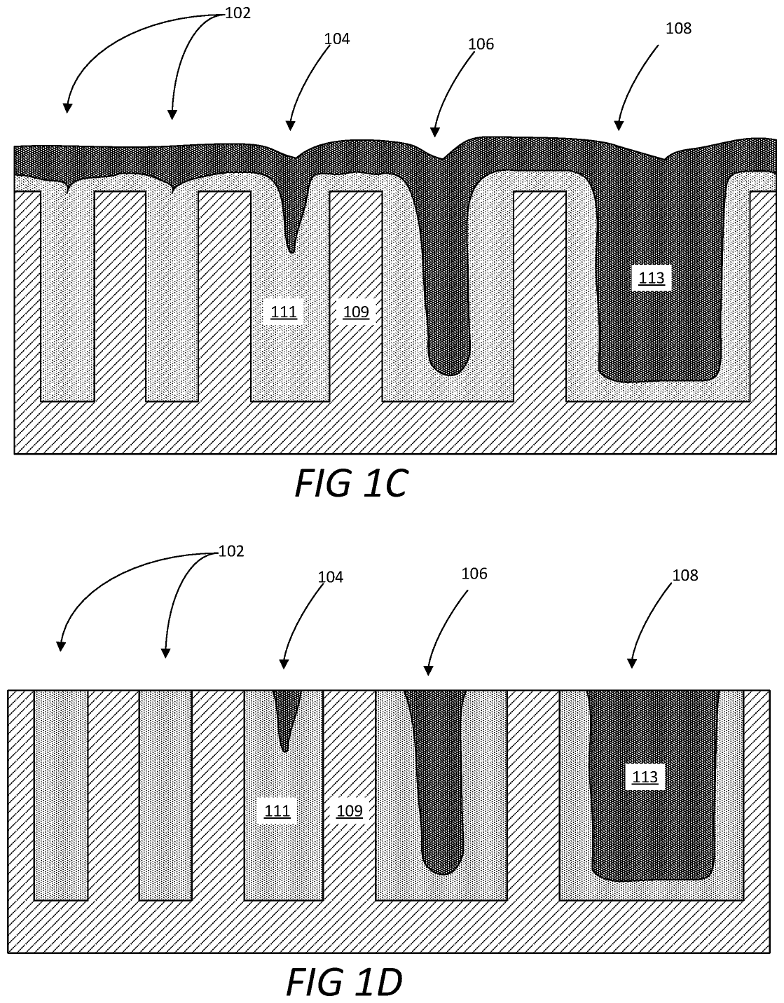

One aspect of the disclosure relates to filling features on a substrate with conductive material. In some embodiments, the structure includes features of different sizes. FIG. 1a shows an example of such a structure, which includes small features 102 and larger features 104, 106, and 108 etched in dielectric layer 109. Each feature 102, 104, 106, and 108 has a bottom surface and sidewall surfaces.

In some embodiments, the bottom surface of a feature may be a metal surface such as such as cobalt (Co), ruthenium (Ru), copper (Cu), W, Mo, nickel (Ni), iridium (Ir), rhodium (Rh), tantalum (Ta), and titanium (Ti). In some embodiments, the bottom surface is an elemental metal surface. In some embodiments, the bottom surface can be a metal compound such a titanium nitride (TiN) surface, molybdenum nitride (MoNₓ), tungsten nitride (WN), tungsten carbon nitride (WCₓN_{y}), tungsten carbide (WCx), a titanium aluminum carbide (TiAlₓC_{y}) or tantalum nitride (TaN) surface. The bottom surface can be a part of an underlying metal contact, electrode, or other conductive component (not shown). It may be part of a main conductor of an underlying layer and not a thin layer such as barrier or adhesion layer.

In some embodiments, sidewall surfaces may be dielectric surfaces. Such surfaces include alkoxides such as poly(2-ethyl-2-oxazoline) (PEOX) and silicon-based oxides including tetraethyl orthosilicate (TEOS) oxide, flowable silicon-based oxides, carbon doped silicon-based oxides, etc. In some embodiments, these surfaces are part of the main dielectric layer 109 surrounding the feature. In some embodiments, the sidewall surfaces may be nitrides (e.g., SiₓN_{y}) rather than oxides. The nitrides may be silicon-based nitrides or silicon-based oxynitrides. The surfaces of the features 102, 104, 106, and 108 may be the same or different across features.

FIG. 1b shows the structure after ALD deposition of Mo film 111. The smaller features 102 are fully filled by the ALD Mo film 111, while the larger features 104, 106, and 108 are partially filled by the ALD Mo film 111. ALD of molybdenum is described further below.

FIG. 1c shows the structure after CVD deposition of W film 113. The W film 113 completes the feature fill of larger features 104, 106, and 108. FIG. 1d shows the structure after chemical-mechanical planarization (CMP). As can be seen, the W film 113 forms part of the conductive component (e.g., contact, interconnect, line, etc.) in each of the larger features 104, 106, and 108. The smaller features 102 are filled only with Mo film.

The method and resulting metallization scheme illustrated in FIGS. 1a-1d has various advantages, including that the ALD Mo film 111 is a low resistivity film that may be deposited directly on dielectric and that CVD of W is a fast and scalable process. As a result, the overall stack has low resistivity and may be fabricated efficiently. In alternate embodiments, sputtering or other PVD process may be used to deposit W instead of CVD.

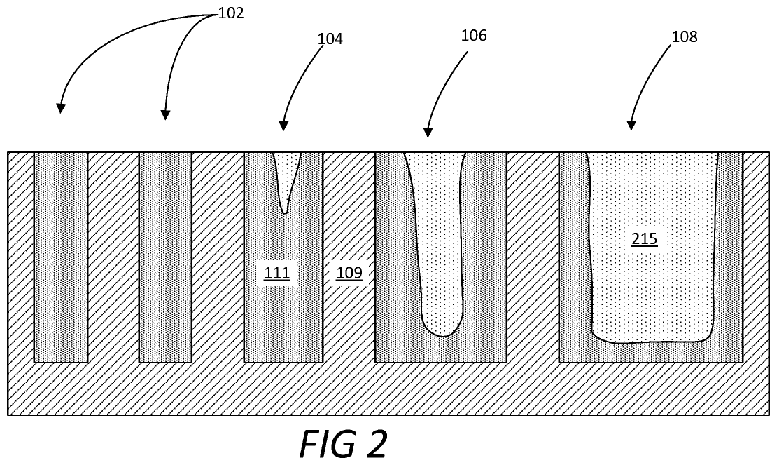

FIG. 2 shows an example of a structure according to another embodiment. In FIG. 2, an ALD Mo film 111 completely fills smaller features 102 and partially fills larger features 104, 106, and 108. CVD Mo film 215 fills the remaining part of the larger features 104, 106, and 108. The Mo film 215 forms part of the conductive component in each of the larger features 104, 106, and 108. In alternate embodiments, sputtering or other PVD process may be used to deposit Mo instead of CVD.

In the examples of FIGS. 1a-1d and 2, the structure includes smaller features that are completely filled by ALD Mo. The methods described herein also may be implemented with a structure that includes only features that are partially filled with ALD Mo. Feature fill is then completed with CVD or PVD W or CVD or PVD Mo as described above.

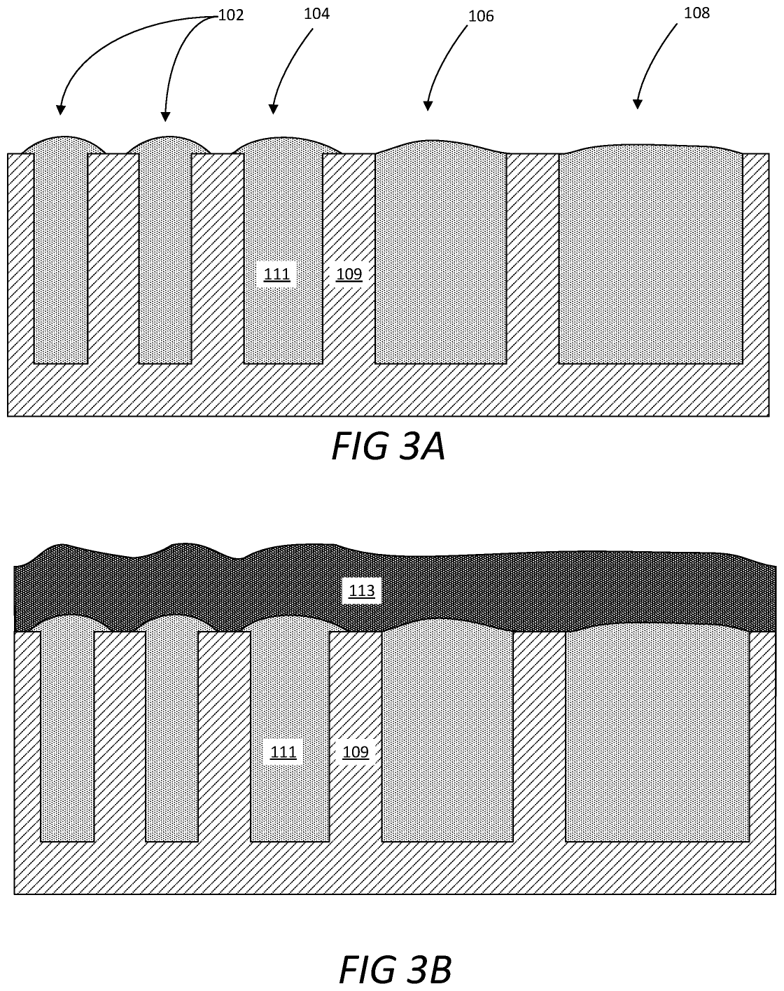

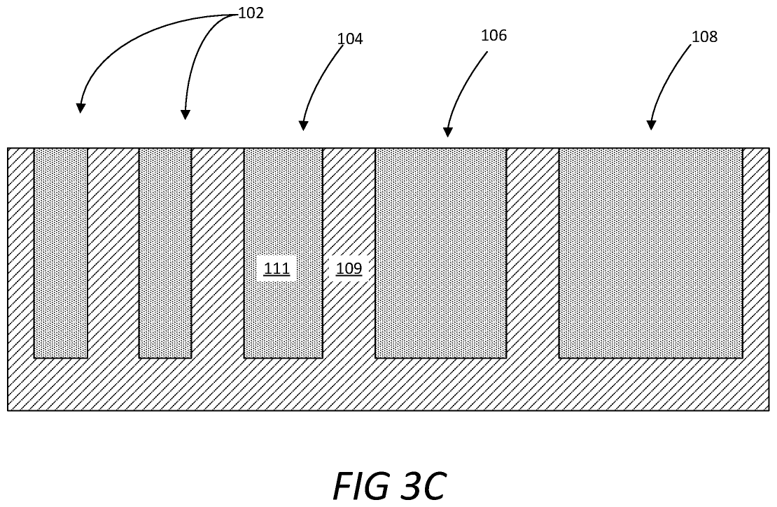

Another aspect of the disclosure relates to methods including filling features with ALD Mo and depositing a sacrificial overburden layer. FIGS. 3a-3c show examples of a structure during such a method. First, in FIG. 3a, a structure as shown in FIG. 1a is filled with ALD Mo film 111. In the example of FIG. 3a, all of the features are completely filled with the ALD Mo film 111. After the ALD fill process, some amount ALD Mo film is deposited over the features 102, 104, 106, and 108. There may also be ALD Mo film deposited on the structure in between features. In FIG. 3b, a W film 113 is deposited by CVD over the filled features. Unlike the W film in Figure id, the W film 113 in FIG. 3b is a purely sacrificial film. Thus, after CMP, only the ALD Mo film 111 is in features 102, 104, 106, and 108 as shown in FIG. 3c. In alternate embodiments, PVD W, CVD Mo, or PVD Mo may be used at the sacrificial film instead of CVD W.

In the context of this description, CVD refers to processes in which reactants exist in vapor phase in the reactor at the same time, and are generally introduced at the same time, while ALD refers to processes that introduces reactants in sequential pulses, typically separated by purges. Example reactants and reaction conditions that may be used for ALD and/or CVD reactions to fill a feature with the conductive material are given below.

In some embodiments, ALD relies on adsorption of one or more reactants to the surface of the substrate, and on subsequent chemical transformation of the adsorbed layer to the desired material. Because ALD uses sequential reactions that occur on the surface of the substrate, that are separated in time, and that are typically limited by the amount of the adsorbed reactant, it provides thin conformal layers having excellent step coverage. In the description below, molybdenum-containing reactants are referred to as Mo precursors and are reacted with co-reactants.

As described further below, in some embodiments, a Mo precursor is reacted with a reducing agent co-reactant to form a pure Mo film. According to various embodiments, each ALD cycle may begin with pulse and adsorption on the surface of either the Mo precursor or the co-reactant, followed by a pulse of the other. In other embodiments, a Mo precursor (e.g., an organometallic Mo precursor) may be reacted with several reactants sequentially. And in other embodiments, an ALD process may involve the decomposition of Mo precursor without a co-reactant.

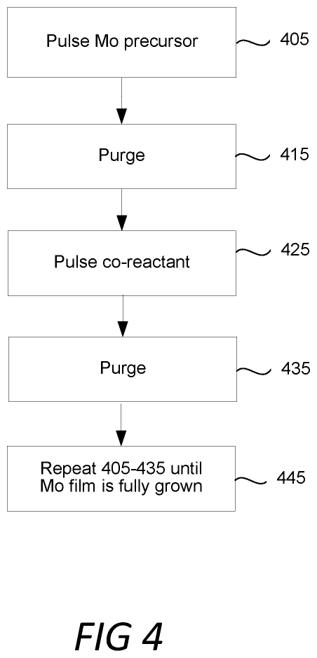

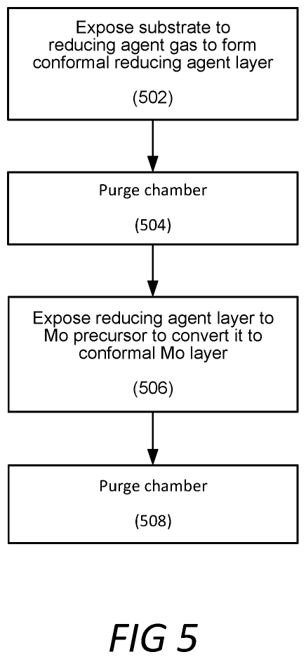

FIG. 4 shows an example of an ALD method of forming a Mo film. First, in an operation 405, a Mo precursor is pulsed into a chamber that contains the substrate having features to be filled. Examples of Mo precursors are provided below. The precursor can be introduced in a vaporized form in a flow of inert gas such as argon (Ar), helium (He), or nitrogen (N₂). After the Mo precursor is pulsed, an optional purge 415 may occur. Argon or any inert gas may be used to purge the chamber of any Mo precursor that remains in the vapor phase. A purge may be conducted by flowing the inert gas at a fixed pressure thereby reducing the pressure of the chamber and re-pressurizing the chamber before initiating another gas exposure. The purge may be performed for a duration between about 0.25 seconds and about 30 seconds, about 0.25 seconds and about 20 seconds, about 0.25 seconds and about 5 seconds, or about 0.5 seconds and about 3 seconds.

The substrate is exposed to a co-reactant in an operation 425. As indicated above, the co-reactant may be a reducing agent to reduce the Mo precursor and form elemental Mo. In other embodiments, any appropriate co-reactant or co-reactants that react with the Mo precursor to form elemental Mo. The reactant may be a hydrogen-containing reactant. In some embodiments, the hydrogen-containing reactant may be thermal (non-plasma) hydrogen (H₂).

In a plasma-based process, a remote or in-situ plasma generated from H₂ may be used. An optional purge may be performed at 435, followed by repeating operations 405-435 until the film is fully grown in an operation 445. According to various embodiments, this may be when a feature is partially or wholly filled as described above with respect to FIGS. 1a-3.

Substrate temperature during Mo deposition may be between 300° C. to 750° C., and in particular embodiments, between 450° C. and 550° C. Substrate temperature will depend on the thermal budget and the deposition chemistry. Thermal budget depends on the application; while high deposition temperature may not be an issue for memory applications, it can exceed the thermal budget for logic applications.

The ALD Mo layer deposited in FIG. 4 forms all or part of a bulk conductive material in the feature as describe above with respect FIGS. 1-3. In some embodiments, it may be deposited on a Mo nucleation layer that is formed by a separate ALD process. A nucleation layer is a thin conformal layer that can be used to support bulk deposition. In some embodiments, a Mo nucleation layer is deposited using one or more of a boron-containing reducing agent (e.g., B₂H₆) or a silicon-containing reducing agent (e.g., SiH₄) as a co-reactant. For example, one or more S/Mo cycles or Mo/S cycles may be used to deposit a Mo nucleation layer. S/Mo refers to a pulse of silane followed by a pulse of a Mo-containing precursor. In another example, one or more B/Mo cycles or Mo/B cycles may be used to deposit a Mo nucleation layer on which a bulk Mo layer is deposited. B/Mo and S/Mo cycles (or Mo/B and/or Mo/S) may both be used to deposit a Mo nucleation layer, e.g., x(B/Mo)+y(S/Mo), with x and y being integers. Examples of B- and S-containing reducing agents are given below. For deposition of a Mo nucleation layers, in some embodiments, the Mo-containing precursor may be a non-oxygen containing precursor, e.g., molybdenum hexafluoride (MoF₆) or molybdenum hexachloride (MoCl₆). Oxygen in oxygen-containing precursors may react with a silicon- or boron-containing reducing agent to form MoSiₓO_{y} or MoBₓO_{y}, which are impure, high resistivity films. Oxygen-containing precursors may be used with oxygen incorporation minimized. In some embodiments, H₂ may be used as a reducing gas for Mo nucleation layer deposition instead of a boron-containing or silicon-containing reducing gas. Example thicknesses for deposition of a Mo nucleation layer range from 5 Å to 30 Å. Films at the lower end of this range may not be continuous; however, as long as they can help initiate continuous bulk Mo growth, the thickness may be sufficient.

In some embodiments, the reducing agent pulses during deposition of a nucleation or bulk Mo layer may be done at lower substrate temperatures than the Mo precursor pulses. For example, or B₂H₆ or a SiH₄ (or other boron- or silicon-containing reducing agent) pulse may be performed at a temperature below 300° C., with the Mo pulse at temperatures greater than 300° C.

In some embodiments, ALD formation of a Mo layer can be initiated by a reducing agent layer. An example of such a process is shown in the flow diagram in FIG. 5. In operation 502, the substrate is exposed to a reducing agent gas to form a reducing agent layer.

In some embodiments, the reducing agent gas may be a silane, a borane, or a mixture of a silane and diborane. Further examples of reducing agents are given below. In some implementations, the reducing agent layer may include silicon or silicon-containing material, phosphorous or a phosphorous-containing material, germanium or a germanium-containing material, boron or boron-containing material that is capable of reducing a Mo precursor and combinations thereof.

According to various embodiments, hydrogen may or may not be run in the background. (While hydrogen can reduce tungsten precursors, it does not function as a reducing agent in a gas mixture with a sufficient amount of stronger reducing agents such as silane and diborane.) In some embodiments, the reducing agent gas is a mixture including a small amount of a boron-containing gas, such as diborane, with another reducing agent. The addition of a small amount of a boron-containing gas can greatly affect the decomposition and sticking coefficient of the other reducing agent. It should be noted that exposing the substrate sequentially to two reducing agents, e.g., silane and diborane may be performed. However, flowing a mixture of gases can facilitate the addition of very small amounts of a minority gas, e.g., at least a 100:1 ratio of silane to diborane. In some embodiments, a carrier gas may be flowed. In some embodiments, a carrier gas, such as nitrogen (N₂), argon (Ar), helium (He), or other inert gases, may be flowed during operation 502.

In some embodiments, a reducing agent layer may include elemental silicon (Si), elemental boron (B), elemental germanium (Ge), or mixtures thereof. For example, a reducing agent layer may include elemental Si and B. This is distinct from adsorbed silane or diborane molecules and can involve decomposition of the compounds in the reducing agent gas. The amount of B may be tailored to achieve high deposition rate of the reducing agent layer but with low resistivity. In some embodiments, a reducing agent layer may have between 5% and 80% B for example, or between 5% and 50% B, between 5% and 30%, or between 5% and 20% B, with the balance consisting essentially of Si and in some cases, H. Hydrogen atoms be present, e.g., SiHₓ, BH_{y}, GeH_{z}, or mixtures thereof where x, y, and z may independently be between 0 and a number that is less than the stoichiometric equivalent of the corresponding reducing agent compound. In some embodiments, the composition may be varied through the thickness of the reducing agent layer. For example, a reducing agent layer may be 20% B at the bottom of the reducing agent layer and 0% B the top of the layer. The total thickness of the reducing agent layer may be between 10 Å and 50 Å, and is some embodiments, between 15 Å and 40 Å, or 20 Å and 30 Å. The reducing agent layer conformally lines the feature.

Substrate temperature during operation 502 may be maintained at a temperature T1 for the film to be conformal. If temperature is too high, the film may not conform to the topography of the underlying structure. In some embodiments, step coverage of greater than 90% or 95% is achieved. For silane, diborane, and silane/diborane mixtures, conformality is excellent at 300° C. and may be degraded at temperatures of 400° C. or higher. Thus, in some embodiments, temperature during operation 502 is at most 350° C., or even at most 325° C., at most 315° C., or at most 300° C. In some embodiments, temperatures of less than 300° C. are used. For example, temperatures may be as low as 200° C.

Operation 502 may be performed for any suitable duration. In some examples, Example durations include between about 0.25 seconds and about 30 seconds, about 0.25 seconds and about 20 seconds, about 0.25 seconds and about 5 seconds, or about 0.5 seconds and about 3 seconds.

In operation 504, the chamber is optionally purged to remove excess reducing agent that did not adsorb to the surface of the substrate. A purge may be conducted by flowing an inert gas at a fixed pressure thereby reducing the pressure of the chamber and re-pressurizing the chamber before initiating another gas exposure. Example inert gases include nitrogen (N₂), argon (Ar), helium (He), and mixtures thereof. The purge may be performed for a duration between about 0.25 seconds and about 30 seconds, about 0.25 seconds and about 20 seconds, about 0.25 seconds and about 5 seconds, or about 0.5 seconds and about 3 seconds.

In operation 506, the substrate is exposed to a Mo precursor at a substrate temperature T2. Use of oxygen-containing precursors can lead to impurity incorporation and higher resistivity. However, if oxygen is incorporated, a very thin, possibly discontinuous reducing agent layer may be used for an acceptable resistivity. In some embodiments, a carrier gas, such as nitrogen (N₂), argon (Ar), helium (He), or other inert gases, may be flowed during operation 506. Examples of temperatures are 500° C. to 700° C.

Operation 506 may be performed for any suitable duration. In some embodiments, it may involve a soak of the Mo precursor and in some embodiments, a sequence of Mo precursor pulses. According to various embodiments, operation 506 may or may not be performed in the presence of H₂. If H₂ is used, in some embodiments, it and the Mo-containing precursor may be applied in an ALD-type mode. For example:
Pulse of H₂
Argon purge
Pulse of Mo-containing precursor with or without H₂ in background
Argon purge
Repeat

The substrate temperature T2 is high enough that the Mo-containing precursor reacts with the reducing agent layer to form elemental Mo. The entire reducing agent layer is converted to Mo. In some embodiments, the temperature is at least 450° C., and may be at least 550° C. to obtain conversion of at or near 100%. The resulting feature is now lined with a conformal film of Mo. It may be between 10 Å and 50 Å, and is some embodiments, between 15 Å and 40 Å, or 20 Å and 30 Å. In general, it will be about the same thickness as the reducing agent layer. In some embodiments, it may be up to 5% thicker than the reducing agent layer due to volumetric expansion during the conversion. The chamber may be purged in an operation 508.

An ALD process as described with reference to FIG. 4 may then be performed. The process described in FIG. 5 may be used to deposit Mo directly on an oxide dielectric surface or a surface including a barrier layer such as titanium nitride (TiN).

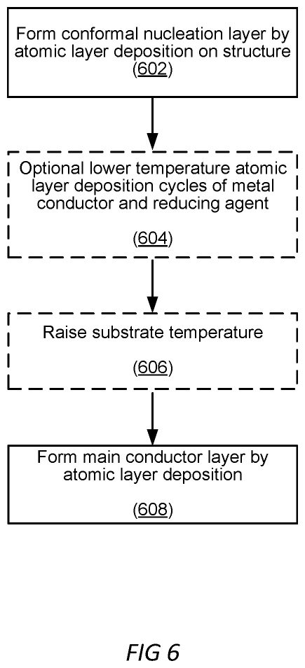

In some embodiments, an ALD Mo film may be deposited directly on oxide or a TiN barrier surface by first depositing a metal nitride or metal oxynitride film that is converted to a pure metal film during subsequent processing. FIG. 6 is a process flow diagram illustrating operations in a method of depositing molybdenum. In operation 602, a conformal nucleation layer is formed on a structure by ALD. As discussed above, this can involve exposing the structure to cycles of sequential pulses Mo precursor and reducing agents with optional purges between the pulses. The cycles may be repeated until a desired thickness of the nucleation layer is formed on the substrate. As described above, the order of precursor and reducing agent may be reversed such that the sequence may be initiated by a reducing agent dose followed by a metal containing precursor dose.

In some embodiments, the reducing agent is ammonia (NH₃) or other nitrogen-containing reducing agent such hydrazine (N₂H₄). NH₃ chemisorption on dielectrics is more favorable than that of hydrogen (H₂). In some embodiments, the reducing agent and precursor are selected such that they react without reducing agent dissociation. NH₃ reacts with metal oxychlorides and metal chlorides without dissociation. This is in contrast to, for example, ALD from metal oxychlorides that uses H₂ as a reducing agent; H₂ dissociates on the surface to form adsorbed atomic hydrogen, which results in very low concentrations of reactive species and low surface coverage during initial nucleation of metal on the dielectric surface. By using NH₃ and metal oxychloride or metal chloride precursors, nucleation delay is reduced or eliminated at deposition temperatures up to hundreds of degrees lower than used by H₂ reduction of the same metal precursors.

In some embodiments, the reducing agent may be a boron-containing or silicon-containing reducing agent such as B₂H₆ or SiH₄. These reducing agents may be used with metal chloride precursors; with metal oxychlorides, however, the B₂H₆ and SiH₄ will react with water formed as a byproduct during the ALD process and form solid B₂O₃ and SiO₂, which are insulating and will remain in the film, increasing resistivity. Use of NH₃ also has improved adhesion over B₂H₆ and SiH₄ ALD processes on certain surfaces including Al₂O₃. The resulting nucleation layer is generally not a pure elemental film but a metal nitride or metal oxynitride film. In some embodiments, there may be residual chlorine or fluorine from the deposition, particularly if the deposition is performed at low temperatures. In some embodiments, there no more than a trace amount of residual chlorine or fluorine. In some embodiments, the nucleation layer is an amorphous layer. Impurities in the film (e.g., oxygen, NH₃, chlorine or other halogen) facilitate growth of an amorphous microstructure. In some embodiments, the nucleation layer as deposited is an amorphous metal oxynitride layer or an amorphous metal nitride layer. The amorphous character templates large grain growth in the subsequently deposited conductor. The surface energy of nitride or oxynitride relative to an oxide surface is much more favorable than that of a metal on an oxide surface, facilitating formation of a continuous and smooth film on the dielectric. This allows formation of thin, continuous layers. Example thicknesses of the nucleation layer range from 5-30 Å as deposited. Depending on the temperature, this may be about 5-50 ALD cycles for example.

As described below, during subsequent processing the nucleation layer may be converted to a pure (or less impure) elemental metal film with the thickness decreasing. The surface on which the nucleation layer is deposited depends on the particular application. In some embodiments, the nucleation layer is deposited directly on a dielectric (e.g., silicon oxide, aluminum oxide, silicon nitride, etc.) surface. In some embodiments, the nucleation layer is deposited directly on a titanium nitride or other surface. As discussed further below, by performing operation 602, the subsequent elemental metal deposition may be performed on any surface.

After deposition of the nucleation layer, an optional operation 604 may be performed. In operation 604, lower temperature ALD cycles of pulses of a molybdenum precursor and a reducing agent are performed.

The “lower” temperature refers to the temperature in operation 604, if performed, being lower than the subsequent operation 606. Example temperatures may be less than 500° C., less than 550° C., less than 450° C., less than 400° C., or less than 350° C. In this operation, the reducing agent is different than in operation 602, and in particular examples may be hydrogen (H₂). In particular, H₂ may result in deposition of an elemental film with significantly fewer impurities than in the nucleation layer. The temperature may be the same temperature as used in operation 602 in some embodiments. The Mo precursor may also be the same or a different precursor than in employed in operation 602. In some embodiments, the same precursor is used, with only the reducing agent changed. In some embodiments, operation 604 may facilitate conversion of the Mo nitride or Mo oxynitride nucleation layer to an elemental metal film. According to various embodiments, operation 604 may or may not deposit an appreciable amount of film of the main conductor.

In a further optional operation 606, the substrate temperature is raised. In some embodiments in which operation 604 is performed, operation 606 is also performed. In other embodiments, only operation 606 may be performed. For example, if the nucleation layer deposition occurs at relatively low temperatures (e.g., below 400° C.), the temperature may be raised in operation 606 to a higher temperature at which deposition of the main conductor will be performed. In some embodiments, the temperature may be greater than 500° C., and in some embodiments, greater than 600° C. In some embodiments, a lower temperature (e.g., between 400° C. and 500° C., endpoints inclusive) may be used for bulk deposition. The temperature may or may not be raised, depending on the temperature of previous operations.

The method may then proceed to an operation 608 (from any of operation 602, 604, or 606) in which a bulk Mo layer is deposited by ALD. As in operation 604 (if performed), H₂ may be used as a reducing agent.

During one or more of operations 604-608, the nucleation layer is converted to an elemental Mo layer. This may also be characterized as removing impurities, i.e., any non-metal constituent. The nucleation layer may have greater impurities than the subsequently deposited elemental Mo layer, but they are sufficiently removed such that the stack resistivity is the same or similar to a stack that does not include a nucleation layer. The thickness will also decrease; for example, a 30 Å as-deposited film may contribute about 10 Å metal to the stack.

According to various embodiments, one or more of the following may be employed to facilitate conversion of the nucleation layer to an elemental Mo film: 1) depositing the bulk Mo layer at a higher temperature (e.g., 550° C.) than the nucleation layer is deposited, 2) performing lower temperature ALD H₂/metal precursor cycles as described with reference to operation 604 above, and 3) in-situ deposition of the bulk Mo layer, such that the nucleation layer is not exposed to air or otherwise oxidized before bulk deposition. Mo oxychlorides in particular are relatively easy to convert to elemental metal. The resulting converted nucleation layer and pure metal layer may each be characterized as having fewer than 1% atomic impurities.

In some embodiments, the feature in which the Mo is deposited has dielectric and metal surfaces. For example, a feature may be etched in a dielectric layer to provide a contact to an underlying conductor. In such embodiments, the Mo may be deposited selectively or non-selectively to the metal surface. Selective deposition refers to the preference in deposition on a metal surface, such as Co, W, or Cu surface relative to a dielectric surface. It may be quantified as a ratio of deposition rates or as a ratio of deposition thicknesses after a certain number of deposition cycles. For a feature having a bottom metal surface, selective deposition results in a bottom-up fill. Non-selective deposition results in a conformal fill. To deposit Mo selectively, Mo oxyhalides, such as MoₓOₓHal_{z} where Hal is a halogen (fluorine (F), chlorine (Cl), bromine (Br), or iodine (I)) and x, y, and z being any number greater than zero that can form a stable molecule may be used. A reducing agent reacts with the molybdenum oxyhalide to form elemental molybdenum. In some embodiments, the reducing agent is thermal or plasma hydrogen (H₂). Temperature affects selectivity, grain size, and resistance. Higher temperatures may reduce selectivity of the Mo film and result in growth on the oxide or nitride of the dielectric surfaces as well as on the metal-containing bottom surface. However, if temperatures are too low, the impurity level may be increased and grain size may be reduced, increasing resistance. Substrate temperature may be between 350° C. and 600° C., inclusive, to selectively deposit Mo using a chlorine-containing chemistry. Selectivity can improve as temperature is lowered. Thus, in some embodiments, substrate temperature may be between about 350° C. and 550° C., or 350° C. and 450° C. for a chlorine-containing precursor. Substrate temperatures for a fluorine-containing chemistry may be lower, e.g., 150° C. to 350° C. Higher temperatures may be used for non-selective deposition.

In some embodiments, the ALD fill of Mo in a feature can involve one or more inhibition and/or etch operations to tailor fill. Nitrogen-containing chemistries can be used to inhibit molybdenum nucleation, for example. In some embodiments, exposure of a molybdenum surface to N₂ plasma or ammonia gas can be used to selectively inhibit further molybdenum nucleation at the top of a feature to facilitate deposition at the feature bottom and bottom up fill. Halogen-containing chemistries can be used to preferentially etch deposited molybdenum at the top of a feature to facilitate deposition at the feature bottom and bottom up fill. The inhibition and etch operations may be used to prevent voids and/or seams developing in filled features.

Examples of Mo precursors for ALD of molybdenum materials include molybdenum halides such MoF₆ and MoCl₆, molybdenum oxyhalides such as molybdenum dichloride dioxide (MoO₂Cl₂) and molybdenum tetrachloride oxide (MoOCl₄), and molybdenum hexacarbonyl (Mo(CO)₆). Other Mo oxyhalides of the formula MoₓOₓHal_{z} where Hal is a halogen (fluorine (F), chlorine (Cl), bromine (Br), or iodine (I)) and x, y, and z are any number greater than zero that can form a stable molecule. These include molybdenum tetrafluoride oxide (MoOF₄), molybdenum dibromide dioxide (MoO₂Br₂), and molybdenum oxyiodides MoO₂I and Mo₄O₁₁I.

In certain embodiments, organo-metallic precursors may also be used with examples including Mo precursors having cyclopentadienyl ligands. Further examples include precursors of the formula Mo₂Lₙ, wherein each L is independently selected from an amidate ligand, an amidinate ligand, and a guanidinate ligand, where n is 2-5. The Mo₂Lₙ precursor includes a multiple molybdenum-molybdenum bond (such as a double bond or any multiple bond with a bond order of 2-5). Further examples include halide-containing heteroleptic molybdenum compounds (i.e., compounds having different types of ligands). Particular examples of such precursors are compounds that include molybdenum, at least one halide forming a bond with molybdenum, and at least one organic ligand having any of the N, O, and S elements, where an atom of any of these elements forms a bond with molybdenum. Examples of suitable organic ligands that provide nitrogen or oxygen bonding include amidinates, amidates, iminopyrrolidinates, diazadienes, beta-imino amides, alpha-imino alkoxides, beta-amino alkoxides, beta-diketiminates, beta-ketoiminates, beta-diketonates, amines, and pyrazolates. Examples of suitable organic ligands that provide sulfur bonding include thioethers, thiolates, dithiolenes, dithiolates, and α-imino thiolenes. These ligands may be substituted or unsubstituted. In some embodiments, these ligands include one or more substituents independently selected from the group consisting of H, alkyl, fluoroalkyl, alkylsilyl, alkylamino, and alkoxy substituents. The organic ligands can be neutral or anionic (e.g., monoanionic or dianionic), and molybdenum can be in a variety of oxidation states, such as +1, +2, +3, +4, +5, and +6.

As noted above, many Mo precursors are reacted with a reducing agent to form a Mo film. Examples of reducing agents can include H₂, boron-containing reducing agents including diborane (B₂H₆) and other boranes, silicon-containing reducing agents including silane (SiH₄) and other silanes, hydrazines, and germanes. Examples of silanes include disilane (Si₂H₆) and examples of boranes include BₙHₙ₊₄, BₙHₙ₊₆, BₙHₙ₊₈, BₙHₘ, where n is an integer from 1 to 10, and m is a different integer than m. Other boron-containing compounds may also be used, e.g., alkyl boranes, alkyl boron, aminoboranes (CH₃)₂NB(CH₂)₂, carboranes such as C₂BₙHₙ₊₂.

In some implementations, a separate reactant may not be used, e.g., a metal-containing precursor may undergo thermal or plasma-assisted decomposition. In some embodiments, H₂ is used as a reducing agent for bulk layer deposition to deposit high purity films.

In some embodiments, ALD of Mo is followed by a CVD process. The Mo precursors and co-reactants described above above can be used for CVD of Mo. In such processes, the reactants exist in vapor phase in the reactor at the same time. The reactants are generally (though not necessarily) introduced to the reactor at the same time. In one example, MoF₆ and H₂ are both flowed into the reactor for CVD reaction to form Mo.

In some embodiments, ALD of Mo is followed by CVD process to deposit W. Examples of W-containing precursors for CVD of tungsten include tungsten hexacarbonyl (W(CO)₆) and tungsten halides such as tungsten hexafluoride (WF₆), tungsten hexachloride (WCl₆), and tungsten pentachloride (WCl₅). In some embodiments, tungsten oxy-halides including WO₂Cl₂, WOBr₄, WOCl₄, and WOF₄ may be used. Organo-metallic precursors such as MDNOW (methylcyclopentadienyl-dicarbonylnitrosyl-tungsten) and EDNOW (ethylcyclopentadienyl-dicarbonylnitrosyl-tungsten) may also be used. PVD of Mo or W can be performed by sputter deposition of the target material.

In some embodiments, CVD Mo deposition is preceded by deposition of a Mo nucleation layer on the ALD Mo layer. In some embodiments, a CVD Mo bulk layer is deposited directly on the ALD Mo bulk layer without an intervening nucleation layer. The nucleation layer may be deposited by ALD process in some embodiments as described above.

In some embodiments, CVD W deposition is preceded by deposition of a W nucleation layer on the ALD Mo layer. In some embodiments, a CVD W bulk layer is deposited directly on the ALD W bulk layer without an intervening nucleation layer. A nucleation layer may be deposited by an ALD process using the W precursors and reducing agents described above.

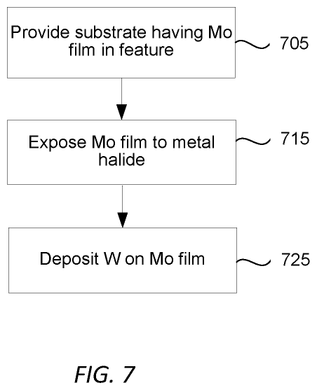

In some embodiments, the ALD Mo layer is treated prior to CVD or PVD deposition of Mo or W. FIG. 7 shows a process according to certain embodiments in which, the ALD Mo film is treated with a metal halide prior to CVD deposition. In FIG. 7, at operation 705, a substrate including an ALD Mo film is provided. As indicated above, the feature may be part of a partially fabricated semiconductor device. In some embodiments, the substrate includes Mo and dielectric surfaces. For example, referring to FIG. 1b, in some embodiments, a surface of dielectric layer 109 may be exposed in larger features (not shown).

The surface of the Mo film may include oxide formed from exposure to air or another oxidative environment. The substrate may be provided to a processing chamber as described further below. The Mo film is exposed to a metal halide in an operation 715. The metal halide is provided as a gas to the chamber housing the substrate and may be pulsed or continuously flowed into the chamber. The metal halide can effectively reduce any oxide on the bottom surface of the feature with little or no damage to dielectric surfaces in the on substrate. This is unlike other halide treatments, which can damage the dielectric. For example, nitrogen trifluoride etches the dielectric, resulting in an increase in the feature critical dimension. The halide compounds are more effective at removing the oxidized layer than other reducing agents such as ammonia or hydrazine.

The metal halide is any that is volatile or has sufficient vapor pressure to be delivered to the substrate at or below the substrate temperature. Example substrate temperatures during operation 715 range from 100° C. to 450° C., and in some embodiments from 350° C. to 450° C. For some metal halides, higher temperatures may result in dielectric etch. The metal halide may contain any appropriate metal including Mo, W, chromium (Cr), titanium (Ti), tantalum (Ta), and vanadium (V), and any halide including fluorine F, Cl, Br, and I. Examples of tungsten halides that may be used include WF₆, WCl₆, tungsten pentachloride WCl₅, and tungsten hexabromide WBr₆. Examples of molybdenum halides that may be used include MoF₆ and MoCl₆. Examples of niobium halides that may be used include niobium pentachloride (NbCl₅), niobium tetraiodide (NbI₄), and niobium pentabromide (NbBr₅). Examples of tantalum halides that may be used include tantalum pentafluoride (TaF₅), tantalum pentaiodide (TaI₅), and tantalum pentachloride (TaCl₅). Examples of vanadium halides that may be used include vanadium pentafluoride (VF₅). Examples of chromium halides that may be used include chromium pentafluoride (CrF₅) and chromium diiodide (CrI₂). Examples of titanium halides that may be used include titanium tetrachloride (TiCl₄).

The metal halide may be mixed with an inert gas such as argon (Ar), helium (He), and the like. This may be used to dilute the metal halide and control the reduction rate. Examples of chamber pressures during operation 315 range from 1 to 30 Torr. Treatment time may range from 2 seconds to 4 minutes, or 2 seconds to 60 seconds. In some embodiments, treatment time may be around 2 minutes to 3 minutes.

It is understood that exposure to a particular metal halide may include exposure to other halides that form in the gas source, gas inlet, and/or chamber. For example, WBr₆ may decompose to tungsten pentabromide (WBr₅) and tungsten tetrabromide (WBr₄) and WF₆ to tungsten pentafluoride (WF₅) and tungsten tetrafluoride (WF₄). A metal halide may take various forms including dimers and other oligomers; for example, MoCl₅ forms a dimer Mo₂Cl₁₀. The metal halides may be oxygen-free. (Some metal oxy-halides, molybdenum tetrachloride oxide (MoOCl₄) can etch/reduce the metal oxide, however, they generally are less effective than the metal halides. Other metal oxy-halides are listed above with reference to the ALD or CVD deposition.) Selection of a particular metal halide depends on the etch selectivity of the metal oxide to the silicon oxide or other dielectric material. At 725, W is deposited on the Mo film. This can be done without a nucleation layer. Operation 725 may involve an CVD or PVD process.

While FIG. 7 shows an example of depositing W on Mo, the metal halide treatment of the ALD Mo layer may be performed prior to deposition of any conductive material according to the integration scheme.

Operations 715 and 725 may be performed in the same chamber or in different chambers, which may or may not be integrated under a common vacuum. In some embodiments, they are performed in different stations of a multi-station chamber.

In some embodiments, the feature surfaces may be susceptible to incorporation of halogen from the metal halide during operation 715. Operation 725 may use relatively high temperatures to help desorb or otherwise remove any incorporated halogen. In some embodiments, exposure to a reducing gas like H₂ at relatively high temperatures may be used to remove residual halogen. Such an operation may take place between operations 715 and 725.

According to various embodiments, the ALD Mo film and a subsequently deposited CVD film may be deposited in the same or different chambers. Further description of apparatus to deposit ALD Mo and/or CVD Mo or CVD W are provided below. PVD deposition typically is performed in a chamber separate from the ALD Mo. In embodiments in which the ALD Mo film and CVD Mo or CVD W film are deposited in the same chamber or in different chambers under a common vacuum, the CVD Mo or W deposition may be performed after the ALD Mo deposition without an intervening metal halide treatment.

### Apparatus

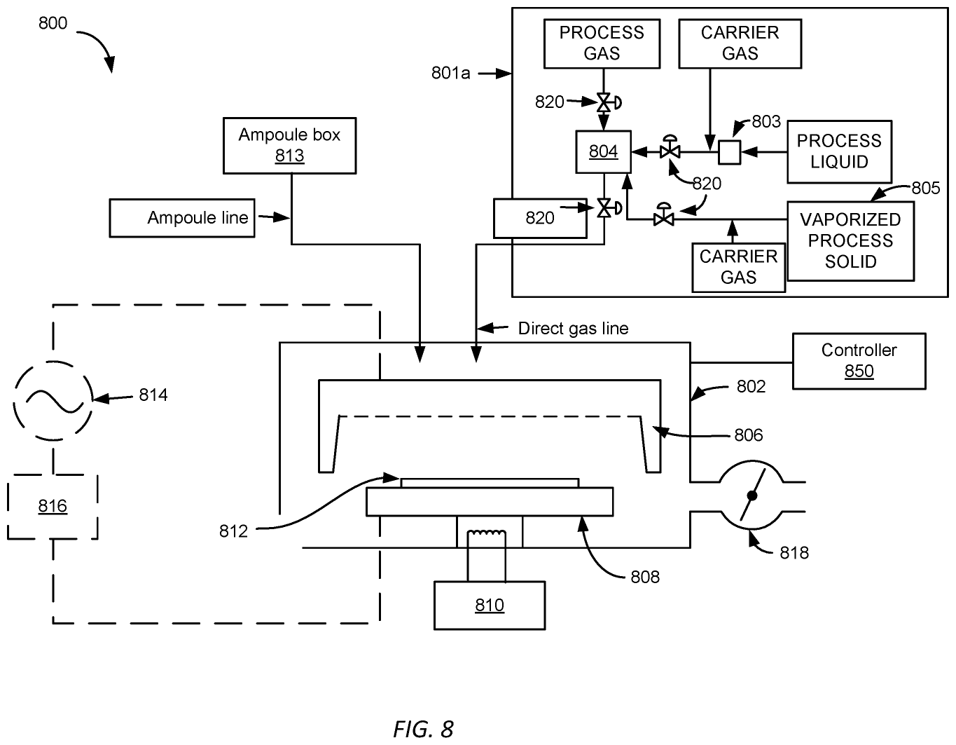

As indicated above, ALD and CVD operations may be performed in the same or different chambers and in the same or different stations. FIG. 8 depicts a schematic illustration of an example of a process station 800 that may be used for ALD and/or CVD. The process station 800 fluidly communicates with reactant delivery system 801a for delivering process gases to a distribution showerhead 806. Reactant delivery system 801a includes a mixing vessel 804 for blending and/or conditioning process gases (such as a metal precursor-containing gas and hydrogen-containing gas for a deposition) for delivery to showerhead 806. One or more mixing vessel inlet valves 820 may control introduction of process gases to mixing vessel 804.

The embodiment of FIG. 8 includes a vaporization point 805 for process solids to be supplied to the mixing vessel 804. In another scenario, vaporization process solids may be supplied directly to the showerhead 806. The vaporization can be sublimation or from solid to liquid to vapor. With the exception of WF₆ and MoF₆, metal halides are generally solid at room temperature.

As an example, the embodiment of FIG. 8 includes a vaporization point 803 for vaporizing liquid reactant to be supplied to the mixing vessel 804. In some embodiments, vaporization point 803 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 804. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 803. In one scenario, a liquid injector may be mounted directly to mixing vessel 804. In another scenario, a liquid injector may be mounted directly to showerhead 606.

In some embodiments, a liquid flow controller (LFC) upstream of vaporization point 803 may be provided for controlling a mass flow of liquid for vaporization and delivery to process chamber 802. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 806 distributes process gases toward substrate 812. In the embodiment shown in FIG. 8, the substrate 812 is located beneath showerhead 806 and is shown resting on a pedestal 808. Showerhead 806 may have any suitable shape and may have any suitable number and arrangement of ports for distributing process gases to substrate 812.

In some embodiments, pedestal 808 may be raised or lowered to expose substrate 812 to a volume between the substrate 812 and the showerhead 806. In some embodiments, pedestal 808 may be temperature controlled via heater 810. Pedestal 808 may be set to any suitable temperature, such as between about 150° C. and about 600° C. during operations for performing various disclosed embodiments. It will be appreciated that, in some embodiments, pedestal height may be adjusted programmatically by a suitable computer controller 850. At the conclusion of a process phase, pedestal 808 may be lowered during another substrate transfer phase to allow removal of substrate 812 from pedestal 808.

In some embodiments, a position of showerhead 806 may be adjusted relative to pedestal 808 to vary a volume between the substrate 812 and the showerhead 806. Further, it will be appreciated that a vertical position of pedestal 808 and/or showerhead 806 may be varied by any suitable mechanism within the scope of the present disclosure. In some embodiments, pedestal 808 may include a rotational axis for rotating an orientation of substrate 812. It will be appreciated that, in some embodiments, one or more of these example adjustments may be performed programmatically by one or more suitable computer controllers 850.

In some embodiments where plasma may be used for PECVD or PEALD, showerhead 806 and pedestal 808 electrically communicate with a radio frequency (RF) power supply 814 and matching network 816 for powering a plasma. In some embodiments, the plasma energy may be controlled by controlling one or more of a process station pressure, a gas concentration, an RF source power, an RF source frequency, and a plasma power pulse timing. For example, RF power supply 814 and matching network 816 may be operated at any suitable power to form a plasma having a desired composition of radical species. Likewise, RF power supply 814 may provide RF power of any suitable frequency. In some embodiments, RF power supply 814 may be configured to control high- and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHz, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 850 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase.

For example, for ALD deposition, a first recipe phase may include instructions for modulating a flow rate of a first reactant gas (e.g., a Mo precursor gas), instructions for modulating the flow rate of a carrier or purge gas, and time delay instructions for the first recipe phase. A second, subsequent recipe phase may include instructions for modulating or stopping a flow rate of a reactant gas (e.g., H₂), and instructions for modulating a flow rate of a carrier or purge gas and time delay instructions for the second recipe phase. It will be appreciated that these recipe phases may be further subdivided and/or iterated in any suitable way within the scope of the present disclosure.

Further, in some embodiments, pressure control for process station 800 may be provided by butterfly valve 818. As shown in the embodiment of FIG. 8, butterfly valve 818 throttles a vacuum provided by a downstream vacuum pump (not shown). However, in some embodiments, pressure control of process station 800 may also be adjusted by varying a flow rate of one or more gases introduced to the process station 800.

As described above, ALD Mo and subsequent CVD operations may be performed in a single station of a single or multi-station chamber, in different stations of a multi-station chamber, or in different chambers. If performed in different chambers, they may be integrated under a common vacuum environment to prevent oxidation of the ALD Mo deposition. Similarly, a metal halide treatment (if performed) may be performed in the same or a different chamber as the subsequent CVD treatment. They may also be under common vacuum to prevent oxidation after the metal halide treatment and removal of metal oxide. In some embodiments, they may not be integrated with the metal halide treatment providing a passivation effect to prevent oxidation, at least for a relatively short time.

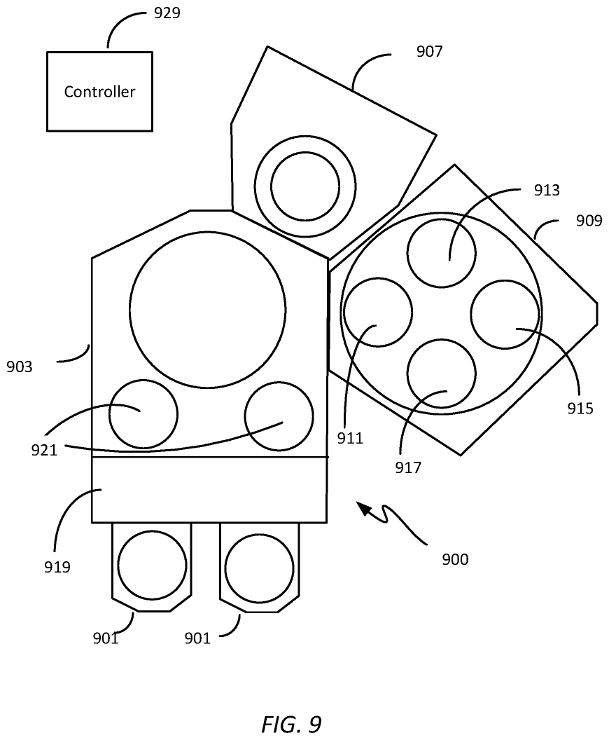

FIG. 9 shows an example of a processing system including multiple chambers. The system 900 includes a transfer module 903. The transfer module 903 provides a clean, vacuum environment to minimize risk of contamination of substrates being processed as they are moved between various reactor modules. Mounted on the transfer module 903 is a multi-station reactor 909 capable of performing ALD and CVD with according to embodiments. In some embodiments, the reactor 909 also performs the metal halide exposure prior to CVD. Nucleation layer deposition (if performed) may be performed in the same or different station or chamber as the subsequent bulk layer deposition.

Reactor 909 may include multiple stations 911, 913, 915, and 917 that may sequentially perform operations in accordance with disclosed embodiments. For example, reactor 909 may be configured such that station 911 performs ALD Mo deposition, station 911 performs a metal halide reducing treatment as described with respect to FIG. 7, and stations 915 and 917 perform bulk layer deposition CVD. In another example, reactor 909 may be configured such that station 911 performs ALD nucleation layer deposition as described with respect to FIG. 6, station 913 performs ALD deposition of bulk Mo, and stations 915 and 917 perform CVD.

Two or more stations may be included in a multi-station reactor, e.g., 2-6, with the operations appropriately distributed. For example, a two-station reactor may be configured to expose the substrate to a metal halide in a first station followed by CVD deposition in a second station. As described above with respect to FIG. 8, stations may include a heated pedestal or substrate support, one or more gas inlets or showerhead or dispersion plate.

Also mounted on the transfer module 903 may be one or more single or multi-station modules 907. In some embodiments, ALD may be performed in a module 907, after which the substrate is transferred under vacuum to another module (e.g., another module 907 or reactor 909) for CVD or PVD deposition.

The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In some embodiments, ALD deposition of Mo is performed in a first chamber, which may be part of a system like system 900, with CVD or PVD deposition of W or other conductive material performed in another chamber, which may not be coupled to a common transfer module, but part of another system. In such cases, substrate may be supplied to source modules of another system for optional metal halide treatment and CVD deposition or PVD deposition.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all the activities of the apparatus. The system controller 929 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 929 may be employed in some embodiments.

Typically, there will be a user interface associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 929. The signals for controlling the process are output on the analog and digital output connections of the deposition apparatus.

The system software may be designed or configured in many ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 929, in some implementations, may be a part of or coupled to a computer that is integrated with, coupled to the system, otherwise networked to the system, or a combination thereof. For example, the controller 929 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a PVD chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 929 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
depositing a bulk layer of molybdenum (Mo) by atomic layer deposition (ALD) in a structure including a plurality of features to at least partially fill the plurality of features with Mo; and
depositing a bulk layer of tungsten (W) on the bulk layer of Mo by chemical vapor deposition (CVD) or physical vapor deposition (PVD).

2. The method of claim 1, wherein the plurality of features includes a first set of one or more features having a first critical dimension and a second set of one or more features having a second critical dimension, the first critical dimension being smaller than the second critical dimension and wherein fill of the features of the first set is completed by depositing the bulk layer of Mo and fill of the features of the second set is completed by depositing the bulk layer of W.

3. The method of claim 1, wherein the fill of at least some of the plurality of features is completed by the bulk layer of W.

4. The method of claim 1, wherein the bulk layer of W is deposited only over the top of the plurality of features and is not within the plurality of features.

5. The method of claim 4, further comprising removing all of the bulk layer of W.

6. The method of claim 1, wherein the plurality of features comprises oxide surfaces prior to any Mo deposition in the features.

7. The method of claim 6, wherein Mo is formed in the plurality of features without a barrier layer disposed between the formed Mo and the oxide surfaces.

8. The method of claim 1, further comprising depositing a nucleation layer prior to depositing the bulk layer of Mo.

9. The method of claim 8, wherein depositing the nucleation layer comprises forming a layer of molybdenum nitride or molybdenum oxynitride.

10. The method of claim 9, further comprising converting the layer of molybdenum nitride or molybdenum oxynitride to molybdenum.

11. The method of claim 1, wherein the bulk layer of Mo and the bulk layer of W are deposited in the same chamber.

12. The method of claim 11, wherein the bulk layer of Mo and the bulk layer of W are deposited in different stations of the same chamber.

13. The method of claim of claim 1, wherein the bulk layer of Mo and the bulk layer of W are deposited in different chambers.

14. The method of claim 13, wherein the different chambers are coupled to a common vacuum environment.

15. The method of claim 14, wherein the different chambers are not coupled to a common vacuum environment.

16. The method of claim 1, further comprising treating the surface of the deposited bulk layer of Mo with a metal halide prior to depositing the bulk layer of W.

17. The method of claim 1, wherein depositing a bulk layer of Mo by atomic layer deposition (ALD) comprises exposing the structure to alternating pulses of a Mo precursor and a co-reactant.

18. The method of claim 17, wherein the Mo precursor is a molybdenum halide or molybdenum oxyhalide.

19. The method of claim 18, wherein the Mo precursor is one of: molybdenum hexafluoride (MoF₆), molybdenum hexachloride (MoCl₅), molybdenum dichloride dioxide (MoO₂Cl₂) molybdenum tetrachloride oxide (MoOCl₄), molybdenum hexacarbonyl (Mo(CO)₆), (MoOF₄), molybdenum dibromide dioxide (MoO₂Br₂), MoO₂I, and Mo₄O₁₁I.

20. The method of claim 1, wherein the Mo precursor is an organo-metallic precursor.

21. A method comprising:
providing a structure including a first set of features to a chamber;
depositing a bulk layer of molybdenum (Mo) by atomic layer deposition (ALD) in a structure including a first set of features to partially fill features with Mo; and
transferring the structure including the features partially filled with Mo out of the chamber.

22. A method comprising:
providing a structure including a first set of features to a chamber, wherein the first set of features are at least partially filled with molybdenum (Mo); and
depositing a bulk layer of tungsten (W) on the Mo.
